(19) United States
(12) Patent Application Publication
(10) Pub. No.: US 2009/0001850 A1
(43) Pub. Date: Jan. 1, 2009

(54) SAW SENSOR WITH ADJUSTABLE PRELOAD

(76) Inventors: Victor Alexandrovich Kalinin, Oxfordshire (GB); Raymond David Lohr, Buckinghamshire (GB); Arthur John Leigh, Oxfordshire (GB)

Correspondence Address: KEUSEY, TUTUNJIAN & BITETTO, P.C., 20 CROSSWAYS PARK NORTH, SUITE 210, WOODBURY, NY, 11797, US

(21) Appl. No.: 12/190,986

(22) Filed: Aug. 13, 2008

(30) Foreign Application Priority Data
Jul. 25, 2008 (GB) 0813717.6

(51) Int. Cl. H01L 41/113

(52) U.S. Cl. 310/313 R

(57) ABSTRACT

A SAW based sensor having a base and a lid engageable with the base to form an internal cavity therewith. A substrate is supported in the cavity on either tile base or the lid 13 and a dimple 16 is formed on the other which extends towards the substrate so as to engage against the substrate and apply a preload thereto. The base and lid include complementary threads by means of which they are attachable to each other. The preload applied to the substrate by the dimple 16 is adjustable by varying the rotational position of the lid relative to the base.

### BACKGROUND OF THE INVENTION

1. Field of the Invention

The present invention relates to SAW sensors having an adjustment for setting the preload, and more particularly to SAW pressure sensors including passive wireless SAW pressure sensors that can be used to measure high pressures

2. The Prior Art

SAW pressure sensors are very well known in practice. They are based either on delay lines or on resonators. They can be either wired or wireless passive devices. In the former case they can be a part of an oscillator feedback loop so the frequency of the (Continuous Wave) CW signal generated by the oscillator will depend on pressure. In the latter case they can be connected to an antenna forming a passive backscatterer. Interrogation of such a passive wireless sensor can be performed by a short RF pulse. The signal reflected from the sensor antenna will carry the information on the phase delays of the SAW (in the case of a reflective delay line sensor) or on the frequency of natural oscillations (in the case of a resonant sensor). After processing, this information will provide the pressure value.

A particular embodiment of the prior art SAW pressure sensing element based on SAW one-port resonators is shown in FIGS. 1A and 1B which is the subject of applicants own earlier European patent no. 1485692. Its main part is a polished substrate 1 made of ST-quartz with three SAW resonators, 9p (PSAW), 9t1 (T1SAW) and 9t2 (T2SAW) having three different resonant frequencies, f₁, f₂ and f₃ respectively. In one particular embodiment these frequencies are: f₁=434.04 MHz, f₂=433.88 MHz, f₃=433.45 MHz so that they are within the European ISM band and the device can be used as a wireless passive sensor without a need to obtain a license for its operation. The SAW die is attached to the metal base 3 of the package by means of adhesive in such a way that it sits on two ledges 2. The metal lid 5 covering the die has a dimple 4 that presses upon the SAW die even if the outside pressure equals the pressure inside the package. The lid 5 plays the role of a diaphragm being deformed by the external pressure. The dimple 4 transmits this deformation to the SAW substrate 1 and strains it in the area where the resonator 9p (PSAW) is positioned. As a result, its frequency f₁ linearly increases with pressure. If an antenna is connected to the terminals of 9p (PSAW), its resonant frequency can be measured wirelessly following the teaching of applicant's own earlier British Patent No. 2379506 giving information about pressure. However, to exclude the influence of potentially variable antenna impedance, a reference resonator 9t1 (T1SAW) is connected in parallel to 9p (PSAW). T1SAW (9t1) is not strained and its frequency f₂ does not depend on pressure so, measuring Fₚ=f₁−f₂, one can obtain the reading depending on pressure but not depending on the antenna impedance. It turns out that Fₚ still depends on temperature so that temperature compensation is required for the sensor. It is achieved by connecting one more resonator, 9t2 (T2SAW), electrically in parallel to the two others. Since its orientation differs from the orientation of 9t1 (T1SAW) it has a different temperature characteristic to f₃. By measuring Fₜ=f₂−f₃ together with Fₚ, both pressure and temperature can be determined.

It is vitally important for the operation of the pressure sensor shown in FIG. 1 to maintain mechanical contact between the dimple 4 and the substrate 1 of the SAW die at all temperatures and pressures within its operating range, e.g. from −40° C. to +125° C. This requires precise mechanical preloading of the substrate 1 during packaging, i.e. during attaching the lid 5 to the base 3. This attachment is done either by welding or by bonding but in all cases manufacturing tolerances lead to a wide spread of achieved preloading and thus to a large spread of f₁ after packaging. If the measured pressure does not exceed 100-200 psi, then the required lid thickness is well below 1 mm. In this case, the amount of preloading and the value of f₁ can be trimmed after packaging using a laser-welding system such as is disclosed in applicants own earlier UK Patent Application No. 0613060.3. However, if the pressure to be measured is as high as 3000-5000 psi, the lid thickness of the package shown in FIG. 1 becomes so large that the laser trimming cannot be used any more. Mechanical preloading of the sensor becomes very difficult.

### SUMMARY OF THE INVENTION

The aim of the present invention is therefore to provide a simplified system for setting the preload of a SAW sensor which overcomes the problems of the prior art. A further aim is to provide a package for a SAW pressure sensing die that will allow the sensor to work at high pressure and simplify the assembly procedure and thus reduce the sensor cost.

According to the present invention there is provided a SAW based sensor comprising a base, a lid engageable with the base to form an internal cavity therewith, a substrate supported in the cavity on one of said base and said lid and a projection formed on the other of the base and tile lid which extends towards the substrate so as to engage against the substrate and apply a preload thereto, wherein the base and lid include complementary threads by means of which they are attachable to each other, the preload applied to the substrate by the projection being adjustable by varying the rotational position of the lid relative to the base.

A SAW based sensor in accordance with the invention has the advantage that the provision of a thread coupling between the lid and the base enables separation of the lid relative to the base, and hence load applied to the substrate by the projection, to be adjusted and set very easily by simply screwing the lid onto or off of the base or vice versa. Once the desired preload is achieved, the lid and base can then be permanently secured together, for example by means of a thread-lock adhesive, welding or the like so as to prevent accidental relative rotation between the two parts.

Preferably, the projection and the substrate are each centrally located on the respective parts so that the projection, which is preferably a dimple, engages the center of the substrate regardless of the relative rotation between the lid and the base.

The substrate is preferably supported on the lid on a pair of radially spaced apart ledges formed on an inner surface of the lid which faces towards the base, the ledges being symmetrically located on either side of the center of the lid and extending parallel to each other. The dimple is then formed in the center of the facing surface of the base.

Preferably the lid is a cylindrical cap having a female thread formed on its inner cylindrical surface which engages with a complementary male thread formed on an outer circumferential surface of the base. The engagement between the lid and the base, will, of course, form a hermetic seal such that the cavity can be maintained at a different pressure to the surrounds, thereby enabling monitoring of pressure.

The base is preferably also formed as a blind cylinder with one end being closed off and carrying the projection on its outer face. The outer circumferential surface of said one end is then threaded for engagement with the thread of the lid. The blind bore formed in the base is then, in use, fluidly coupled to a pressurised environment whose pressure is to be monitored, the one end of the base which separates the cavity formed between the base and the lid from the blind bore acting as a diaphragm which responds to changes in the pressure in the blind bore by varying the load applied by the dimple to the substrate. This, in turn, is detected by a SAW device mounted on the substrate.

The configuration is particularly applicable for use in measuring high pressure. The thickness and the diameter of the diaphragm can be selected/adjusted to control the flexibility of the diaphragm so that the maximum pressure to which the diaphragm is exposed does not result in an amount of strain in the SAW substrate being induced which would cause the resulting frequency shift to exceed the value limited by the ISM band width.

The outer surface of the base proximate to the open end of the cylinder advantageously also has a thread formed thereon by means of which, in use, the base may be screwed into a pipe, tank or the like whose inner environment is to be monitored, thereby exposing the blind bore and hence the inner surface of the diaphragm to the pressure to be monitored. A suitable seal will, of course, be provided to ensure a fluid tight coupling between the base and the pipe/tank.

Preferably the closed end of the base is thinner in a central region which overlies the blind bore and acts as a diaphragm than the region which surrounds the central region. This ensures that a robust region is provided for carrying the thread which mates with the lid whilst the diaphragm responsiveness can be set to meet the required. Moreover, the thicker outer section will be less susceptible to deformation during heating, enabling welding to be used to permanently fix the lid to the base without requiring subsequent tuning/trimming.

### BRIEF DESCRIPTION OF THE DRAWINGS

In order that the invention may be well understood, there will now be described an embodiment thereof, given by way of example, reference being made to the accompanying drawings, reference being made to the accompanying drawings:

FIG. 1A is a partial cross-sectional view of a prior art SAW sensor.

FIG. 1B is a top plan view of the substrate of the prior art SAW sensor.

FIG. 2A is a side elevational view of a pressure sensor embodying the present invention.

FIG. 2B is a cross sectional view taken along the line A-A from FIG. 2A.

FIG. 2C is an enlarged view of a portion of the sensor of FIG. 2B.

FIG. 2D is a perspective view of the sensor.

### DETAILED DESCRIPTION OF THE PREFERRED EMBODIMENTS

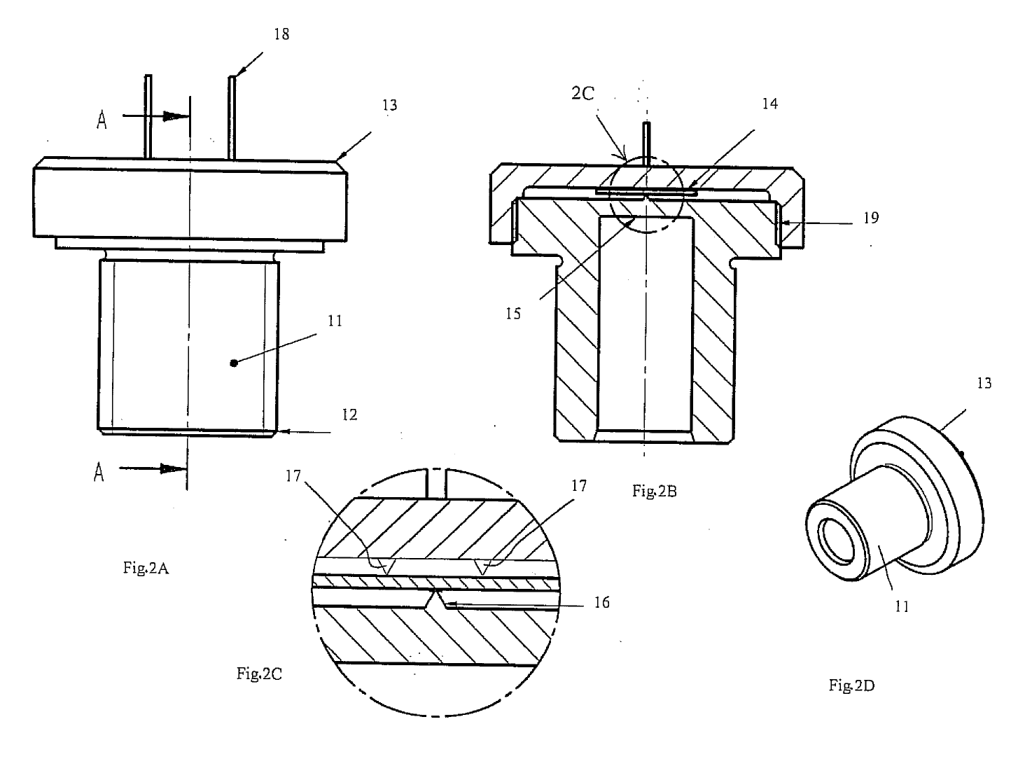

To facilitate mechanical preloading of the existing SAW sensing die, and simplify application of high pressure to the sensor, a new package is proposed according to the present invention as shown in FIGS. 2A, 2B, 2C and 2D. The package consists of two cylindrical parts, a base 11 with a thread 12 and a tubular hole, and a lid 13. The thread 12 is used to screw the sensor into a high-pressure pipeline or a tank so that the high pressure acts upon the diaphragm 15 formed in the base 11. Base 11 and lid 13 cooperatively form a substrate-receiving cavity therebetween. The SAW sensing die 14 is attached to the two ledges 17 formed on the inner surface of the lid 13. The ledges face towards the base, and are symmetrically located on either side of the center of the lid and extend parallel to each other. A projection, preferably formed as a dimple, is disposed in the center of the base. In an alternate embodiment, the ledges are formed on the base and the dimple is formed on the lid.

There are also two pins 18 with at least one of them electrically isolated from the lid 13. Two electrical terminals of the SAW die are connected to the two pins inside the package. The two pins can be used to connect the sensor to any suitable type of antenna if the sensor is used as a wireless passive transponder. Alternatively they can be used to connect the sensor to any interrogation electronic circuitry.

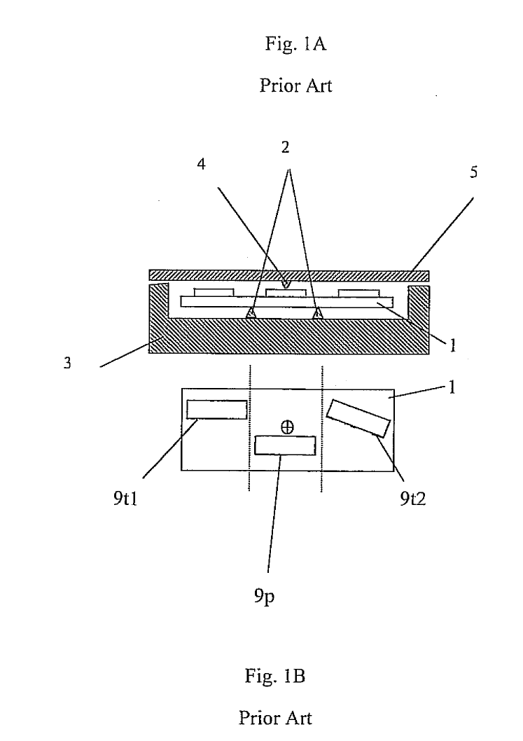

The package presented in FIGS. 2A, 2B, 2C and 2D differs from the prior art package (FIGS. 1A and 1B) in two aspects. The first one is the above-mentioned tube formed in the threaded base 11 and closed by the diaphragm 15. This arrangement facilitates application of high pressure and deformation of the SAW die 14 through the dimple 16 made on the outer surface of the diaphragm. The thickness of the tube walls is sufficiently high to prevent their excessive deformation. The thickness of the diaphragm 15 and its diameter are selected in such a way that the amount of strain in the SAW substrate induced by the maximum pressure causes the PSAW frequency shift that does not exceed the value limited by the ISM band width.

Examples of the dimensions are presented in the table below for the maximum pressure of 5000 psi.

| Diameter of the diaphragm, mm | Thickness of the diaphragm, mm |
|---|---|
| 11 | 2.3 |
| 8 | 1.5 |

As an example, FIG. 2A is shown in a scale of 3:1, that is, the drawing is three times larger than the actual device. As a further example, FIG. 2D is shown in a scale of 1.5:1, that is, the drawing is 1.5 times larger than the actual device.

The second aspect is the way in which preloading of the SAW die is performed. The lid 13 and the base 11 have a thread 19 with a sufficiently small pitch such that the base 11 is screwed into the lid 13 after bonding the SAW die 14 to the pins 18 until the dimple 16 starts touching the die 14. This moment can be easily detected by means of monitoring the PSAW resonant frequency f₁, for example, using a network analyser. As soon as f₁ increases up to its target value screwing should be stopped and the lid should be welded (or bonded by an adhesive) to the base to provide hermeticity. Thus, the fine pitch thread 19 on the base and on the lid facilitates a relatively simple automated preloading process during packaging of the pressure sensor. Relatively large thickness of the base and the lid, in the region where they are welded to each other, minimise their deformation during welding and thus may eliminate the need for subsequent trimming of the sensor and thus drastically reduce its cost.

What is claimed is:

1. A SAW based sensor comprising:
a base and a lid engageable with the base to form an internal cavity therewith; and
a substrate supported in the cavity on one of said base and said lid and a projection formed on the other of the base and the lid which extends towards the substrate so as to engage against the substrate and apply a preload thereto,
wherein the base and lid include complementary threads by means of which they are attachable to each other, the preload applied to the substrate by the projection being adjustable by varying the rotational position of the lid relative to the base.

2. The SAW based sensor according to claim 1, wherein the projection and the substrate are each centrally located on the respective parts so that the projection, which is preferably a dimple, engages the center of the substrate regardless of the relative rotation between the lid and the base.

3. The SAW based sensor according to claim 2, wherein the projection comprises a dimple.

4. The SAW based sensor according to claim 1, wherein the substrate is supported on the lid on a pair of radially spaced apart ledges formed on an inner surface of the lid which faces towards the base, the ledges being symmetrically located on either side of the center of the lid and extending parallel to each other.

5. The SAW based sensor according to claim 4, wherein the projection is formed in the center of the facing surface of the base.

6. The SAW based sensor according to claim 1, wherein the lid is a cylindrical cap having a female thread formed on its inner cylindrical surface which engages with a complementary male thread formed on an outer circumferential surface of the base.

7. The SAW based sensor according to claim 6, wherein the base is formed as a blind cylinder with one end being closed off and carrying the projection on its outer face, the outer circumferential surface of said one end being threaded for engagement with the thread of the lid.

8. The SAW based sensor according to claim 7, wherein the one end of the base, which separates the cavity formed between the base and the lid from the blind bore, acts as a diaphragm which responds to changes in the pressure in the blind bore, varying the load applied by the dimple to the substrate.

9. The SAW based sensor according to claim 7, wherein the outer surface of the base proximate to the open end of the cylinder has a thread formed thereon by means of which, in use, the base may be screwed into a vessel whose pressure is to be monitored, thereby exposing the blind bore and hence the inner surface of the diaphragm to the pressure to be monitored.

10. The SAW based sensor according to claim 7, wherein the closed end of the base is thinner in a central region which overlies the blind bore and acts as the diaphragm.

11. A method of adjusting the preload of a SAW based sensor comprising the steps of:
providing a base and a lid engageable with the base to form an internal cavity therewith; and
supporting a substrate in the cavity on one of said base and said lid and a projection formed on the other of the base and the lid which extends towards the substrate so as to engage against the substrate and apply a preload thereto, wherein the base and lid include complementary threads by means of which they are attachable to each other, the preload applied to the substrate by the projection being adjustable by varying the rotational position of the lid relative to the base;
effecting relative rotation between the base and the lid in order to vary the separation there-between and hence vary the engagement between the projection and the substrate; and
securing the lid to the base against further relative rotation once the desired preload has been achieved.

12. The method according to claim 11, wherein the step of securing the lid to the base is achieved by means of welding.

13. The method according to claim 1, wherein the step of securing the lid to the base comprises securing the lid to the base with an adhesive.

14. The method according to claim 13, wherein the adhesive is applied to the threads of at least one of the lid and the base.
